(19) United States
(12) Patent Application Publication
(10) Pub. No.: US 2017/0186500 A1
(43) Pub. Date: Jun. 29, 2017

(54) Memory circuit defect correction

(71) Applicant: INTEL CORPORATION, Santa Clara, CA (US)

(72) Inventors: Ravi H. Motwani, San Diego, CA (US); Zion S. Kwok, Vancouver (CA); Poovaiah M. Palangappa, Santa Clara, CA (US)

(21) Appl. No.: 14/998,240

(22) Filed: Dec. 23, 2015

(51) Int. Cl. G11C 29/44; G06F 11/16; G06F 11/25; G11C 16/26; H03M 13/29

(52) U.S. Cl. CPC G11C 29/44; G11C 16/26; H03M 13/2906; G06F 11/25; G06F 11/1612

(57) ABSTRACT

Memory circuit defect correction in accordance with one aspect of the present description, logically divides a block of data bits into a plurality of data bit sections, each data bit section to be written into and stored in an associated memory section of a block of memory logically divided into a plurality memory sections. In one embodiment, for each data bit section and its associated memory section, the logical values of all the user data bits of the data bit section are selectively flipped so that the logical value of a user data bit to be written into a defective bitcell, matches the fixed read output of a defective bit cell. A bitcell in each memory section may be utilized to set a flip-flag to indicate whether or not the data bits of the memory section have been flipped. Other aspects are described herein.

### TECHNICAL FIELD

The present invention relates generally to memory devices which may have defective bitcells.

### BACKGROUND

Random access memories (RAMs) often utilize bitcells to store data, typically one bit of data is stored in each bitcell. A charge may be stored in each bitcell to represent either a logical one value or a logical zero value, depending upon the charge level stored in the bitcell. To read the data stored in the bitcells, the charge level stored in a bitcell may be read, and assigned either a logical one value or a logical zero value, depending upon the charge level read from the bitcell.

However, some bitcells may be defective, hindering or eliminating the charge storage capabilities of the bitcell. For example, a bitcell may have an open circuit which fixes the output of the open circuit bitcell at a particular logical value, such as a logical one, for example, regardless of the charge level of any write data which was attempted to be stored in the bitcell. As another example, a bitcell may have a short circuit which fixes the output of the open circuit bitcell at a particular logical value, such as a logical zero, for example, again, regardless of the charge level of any write data which was attempted to be stored in the bitcell.

Accordingly, the presence of defective bitcells in a memory can disrupt the proper operation of the memory. One approach by manufacturers of memory products is to test each memory as it is fabricated and discard any memory product having defective bitcells. Such an approach can be economically wasteful, particularly where the vast majority of the bitcells of the memory are fully operational.

Another approach is to repair a memory having defective memory bitcells by replacing defective bitcells with operational spare bitcells which may be positioned on the same memory die as the defective bitcells. Such an approach is limited by the number of spare bitcells available to replace defective bitcells.

Yet another approach is to flip the logical values of the write data stored in a memory having a defective bitcell, so that the logical value of the bit stored in the defective bitcell matches the fixed output of the defective bitcell. Thus, if the write data bit to be written to a bitcell having an open circuit defect has a logical zero value, the logical values of all the write data stored in the memory may be flipped so that the write data bit written to the bitcell having the open circuit defect has a logical one value, thereby matching the fixed logical value output (that is, a fixed logical one value) of the bitcell having the open circuit defect, thereby eliminating the error. Conversely, if the write data bit to be written to a bitcell having an open circuit defect has a logical one value, none of the logical values of the write data stored in the memory is flipped so that the write data bit written to the bitcell having the open circuit defect again has a logical one value, thereby matching the fixed logical value output (that is, a fixed logical one value) of the bitcell having the open circuit defect. In this manner, an error due to a single defective bitcell may be eliminated.

However, if a memory has multiple defective bitcells, the write data bits for those multiple defective bitcells are unlikely to be the same. As a result, flipping the contents of the memory is likely to cause only some of the write data for the defective bitcells to match the fixed output of the defective bitcells. The remainder of the write data for the defective bitcells will not match and can lead to erroneous results. It is appreciated, that a memory may have thousands, millions or more defective bitcells.

There are various known error correction code (ECC) techniques for encoding write data to facilitate detecting and correcting data transmission or storage errors. Such error correction codes include block codes such as Reed-Solomon error correction codes, for example, which process data on a block-by-block basis, and convolutional codes , for example, which process data on a bit-by-bit basis. In some applications such as deep space transmission of data between Earth and space probes, and compact disk recording and playback devices, for example, it is known to encode data twice using two different ECC schemes which are concatenated together as an outer ECC scheme and an inner ECC scheme, to operate in sequence on the data. By concatenating the ECC techniques, error detection and correction can be enhanced in some applications, as compared to employing just one of the ECC techniques alone.

### BRIEF DESCRIPTION OF THE DRAWINGS

FIG. 1 is a schematic diagram of one embodiment of a computer architecture device employing memory circuit defect correction in accordance with one aspect of the present description.

FIG. 2 depicts an example of a logical architecture of a memory employing one embodiment of memory circuit defect correction in accordance with the present description.

FIG. 3 is an example of data writing operations of data transfer logic employing memory circuit defect correction logic in accordance with one embodiment of the present description.

FIGS. 4a and 4b depict an example of selective bit flipping of memory circuit defect correction operations for a memory section in accordance with one embodiment of the present description.

FIGS. 5a and 5b depict another example of selective bit flipping of memory circuit defect correction operations for a memory section in accordance with one embodiment of the present description.

FIGS. 6a and 6b depict yet another example of selective bit flipping of memory circuit defect correction operations for a memory section in accordance with one embodiment of the present description.

FIGS. 7a and b depict still another example of selective bit flipping of memory circuit defect correction operations for a memory section in accordance with one embodiment of the present description.

FIGS. 8a and b depict yet another example of selective bit flipping of memory circuit defect correction operations for a memory section in accordance with one embodiment of the present description.

FIG. 9 is an example of data reading operations of data transfer logic employing memory circuit defect correction logic in accordance with one embodiment of the present description.

### DESCRIPTION OF EMBODIMENTS

Memory circuit defect correction in accordance with one aspect of the present description, logically divides a block of data bits into a plurality of data bit sections, each data bit section to be written into and stored in an associated memory section of a block of memory logically divided into a plurality of memory sections. As explained in greater detail below, by logically dividing a block of memory into smaller memory sections, selective data flipping in accordance with the present description can reduce or eliminate data transfer errors due to defective bitcells, notwithstanding that the block of memory may have defective bitcells numbering in the tens, or a hundred or more, depending upon the size of the block of memory.

By logically dividing a block of memory into smaller sections, it is recognized herein that the number of defective bitcells in any one section may be substantially reduced or eliminated. As a result, selective data flipping may be readily applied to each section of the block of memory to reduce or eliminate data transfer or storage errors due to defective bitcells. More specifically, in one embodiment of the present description, for each data bit section and its associated memory section, the logical values of all the user data bits of the data bit section are selectively flipped so that the logical value of a user data bit to be written into a defective bitcell, matches the fixed read output of a defective bit cell.

In another aspect, a bitcell in each memory section may be utilized to set a status bit which may be referred to as a flip-flag to indicate whether or not the data bits of the memory section have been flipped. Accordingly, if the flip-flag has been set for a particular memory section, the user data may be reflipped to its original state upon being read from the memory section. As a result, data transfer errors caused by defective bitcells may be reduced or eliminated, notwithstanding that the memory as a whole may have hundreds, thousands, millions or more defective bitcells.

For example, a memory block of 4096 bits may have tens or a hundred or more defective bitcells. In one embodiment, the 4096 bit block of memory may be logically divided into 32 sections of memory, with 128 bitcells in each memory section for storing user data, and a flip-flag data bit. It is appreciated that the size of the blocks of memory and the size of the memory sections, may vary, depending upon the application.

In accordance with the present description, it is recognized that as a result of the subdivision of the block of memory into sections of memory, most of the memory sections will have no defective bitcells or at most one defective bitcell. Thus, for those memory sections having no defective bitcells, the data transfer and storage operations will be free of errors caused by defective bitcells. For those memory sections having a single defective bitcell, selective data flipping in accordance with the present description may be readily applied to eliminate a data transfer or storage error caused by the defective bitcell. Accordingly, the overall error rate of the memory due to defective bitcells may be reduced.

In one embodiment, the number of memory sections having two or more defective bitcells may be as low as less than 5 percent of the total number of bitcells of the memory section of the block of memory, depending upon the sizes of the memory blocks and memory sections. For those memory sections that have two or more defective bitcells, selective data flipping in accordance with the present description may nonetheless be applied to reduce data transfer or storage errors caused by the defective bitcells. Accordingly, the overall error rate of the memory due to defective bitcells may be further reduced.

In another aspect, memory circuit defect correction in accordance with the present description may be employed as a function of the type of bitcell defect. For example, an open circuit type defective bitcell may have one type of fixed logical value output such as a logical one, for example, whereas a short circuit type defective bitcell may have a different fixed logical value output such as a logical zero, for example.

Thus, for a memory section having a defective bitcell of an open circuit type, memory circuit defect correction in accordance with one aspect of the present description may selectively flip the logical values of all the user data bits of the data bit section so that the logical value of a user data bit to be written into a defective bitcell of an open circuit type, for example, matches the fixed logical one value read output. Conversely, for a memory section having a defective bitcell of a short circuit type, memory circuit defect correction in accordance with the present description may selectively flip the logical values of all the user data bits of the data bit section so that the logical value of a user data bit to be written into a defective bitcell of a short circuit type, for example, matches the fixed read output at the logical zero value.

In another aspect, it is recognized that memory circuit defect correction in accordance with the present description may be combined with other types of error correction such as error correction code (ECC) logic. In one embodiment, ECC encoded read data read from a memory employing memory circuit defect correction in accordance with the present description, may be decoded by error correction code logic to detect and correct data transmission or storage errors. Such error detection and correction based upon error correction codes may be enhanced for a memory employing memory circuit defect correction in accordance with the present description.

For example, a low density parity check code (LDPC) error correction code may incorporate data read by a “soft data read” which assigns various levels of confidence ratings such as high confidence and low confidence ratings. It is recognized herein that read errors caused by open circuit or short circuit bitcell defects may erroneously be assigned a high confidence rating, thereby degrading the LDPC error detection and correction process. By reducing or eliminating errors caused by open circuit or short circuit bitcell defects, the overall ECC data correction performance may be enhanced.

In one embodiment, memory circuit defect correction in accordance with the present description is applied to NAND flash memory. In another embodiment, memory circuit defect correction in accordance with the present description is applied to a three dimensional (3D) crosspoint memory. Memory circuit defect correction in accordance with the present description may be applied to systems employing a variety of different types of memory devices including in addition to the aforementioned NAND flash memory and three dimensional (3D) crosspoint memory, non-volatile memory such as spin torque transfer (STT) Random Access Memory (RAM), phase change memory, magnetic RAM, a resistive memory, nanowire memory, ferro-electric transistor random access memory (FeTRAM), flash memory such as NOR, and volatile memory such as 2D RAM, for example. Other types of memory may be suitable as well.

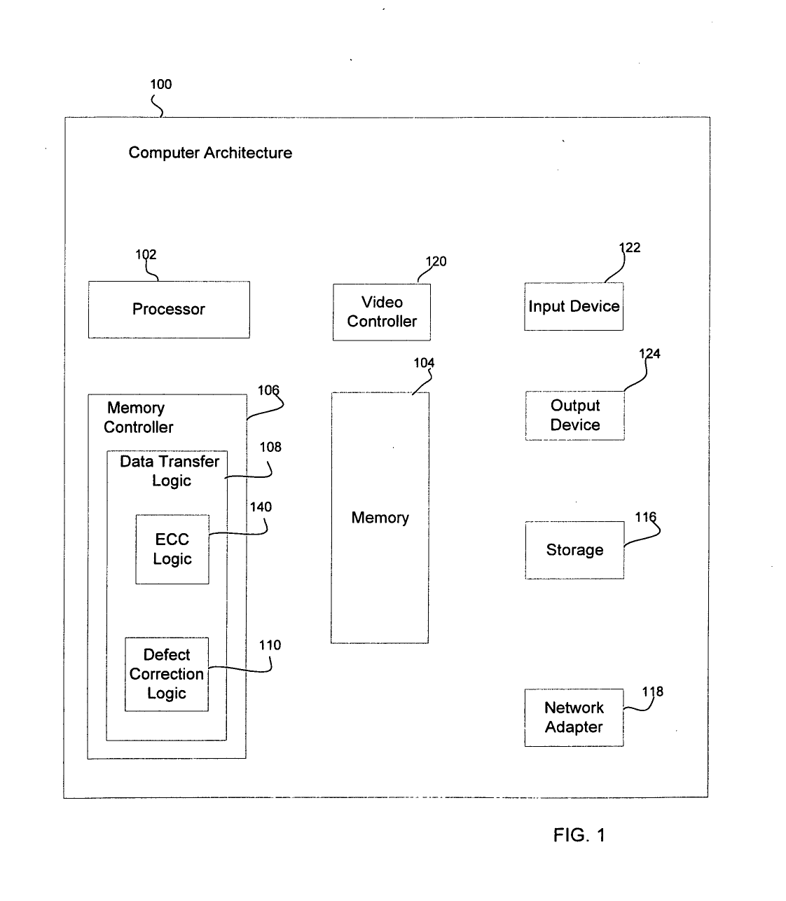

FIG. 1 illustrates one embodiment of a computer architecture device 100 employing memory circuit defect correction in accordance with one aspect of the present description. The computer architecture device 100 may comprise any computing device known in the art, such as a mainframe, server, personal computer, workstation, telephony device, network appliance, virtualization device, storage controller, portable or mobile devices (e.g., laptops, netbooks, tablet computers, personal digital assistant (PDAs), portable media players, portable gaming devices, digital cameras, mobile phones, smartphones, feature phones, etc.) or component (e.g. system on a chip, processor, bridge, memory controller, memory, etc.). The architecture device 100 may include a processor 102 (e.g., a microprocessor), a memory 104 (e.g., a volatile or nonvolatile memory device), and a memory controller 106 having data transfer logic 108 configured to control input and output operations to and from the memory 104, such as data write and data read operations, for example.

As explained in greater detail below, the logic 108 of the memory controller 106 includes a memory circuit defect correction logic 110 which is configured to identify the location of a defective bitcell in a memory section and selectively flip the user data bits of the data bit section written or to be written to that memory section so that the logical value of the user data bit written to the defective bitcell matches the fixed logical value output of the defective bitcell. As a result, errors due to defective bitcells in each memory section may be reduced or eliminated. In one embodiment, the data transfer logic 108 may further include error correction code (ECC) logic 140 to detect and correct errors using an error correction code.

In the illustrated embodiment, the logic 108 of the memory controller 106 is disposed on one or more semiconductor dies within the device 100 and the memory circuit defect correction logic 110 may be disposed on the same die or dies of the memory controller 106. Although the memory circuit defect correction logic 110 is depicted as a part of the memory controller 106, it is appreciated that the memory circuit defect correction logic 110 may be fabricated as a part of other circuits of the computer architecture device 100. For example, in one embodiment, one or more of the memory dies of the memory 104 may be included in the same package as the logic die or dies for the memory controller 106 or the memory circuit defect correction logic 110. Alternatively, one or more of the memory dies of the memory 104 may be housed outside the package of the logic die, on top of the logic die, adjacent to the logic die or on a plug in module such as a dual in line memory module (DIMM). The data transfer logic 108 including the defect correction logic 110 may be implemented with software, hardware, firmware or combinations thereof. As used herein, the term “automated” includes fully automated in which memory circuit defect correction operations in accordance with the present description take place without any user intervention. Also, the term “automated” includes substantially automated in which memory circuit defect correction operations in accordance with the present description take place with limited user intervention. However, in substantially automated operations, most of memory circuit defect correction operations proceed without any user intervention. In one embodiment, the memory circuit defect correction operations in accordance with the present description are fully automated and take place without any user intervention. In other embodiments, at least 50%, at least 75% or at least 95% of the memory circuit defect correction operations proceed without any user intervention.

The computer architecture device 100 may further include storage 116 (e.g., a non-volatile storage, such as magnetic disk drives, optical disk drives, a tape drive, flash memory, etc.). The storage 116 may employ memory circuit defect correction in accordance with the present description, and may comprise an internal storage device or an attached or network accessible storage. Programs in the storage 116 are loaded into the memory 104 and executed by the processor 102 in a manner known in the art.

The computer architecture device 100 further includes a network controller or adapter 118 to enable communication with a network, such as an Ethernet, a Fiber Channel Arbitrated Loop, etc. Further, the architecture may, in certain embodiments, include a video controller 120 configured to control a display in response to the processor, to render information on a display. The video controller 120 may be embodied on a video card or integrated on integrated circuit components mounted on a motherboard or other substrate. An input device 122 is used to provide user input to the processor 102, and may include a keyboard, mouse, pen-stylus, microphone, touch sensitive display screen, input pins, sockets, or any other activation or input mechanism known in the art. An output device 124 is capable of rendering information transmitted from the processor 102, or other component, such as a display screen or monitor, printer, storage, output pins, sockets, etc. The network adapter 118 may embodied on a network card, such as a Peripheral Component Interconnect (PCI) card, PCI-express, or some other I/O card, or on integrated circuit components mounted on a motherboard or other substrate.

One or more of the components of the device 100 may be omitted, depending upon the particular application. For example, a network router may lack a video controller 120, for example. Also, any one or more of the components of the computer architecture device 100 may include one or more integrated memory circuits having memory circuit defect correction in accordance with the present description.

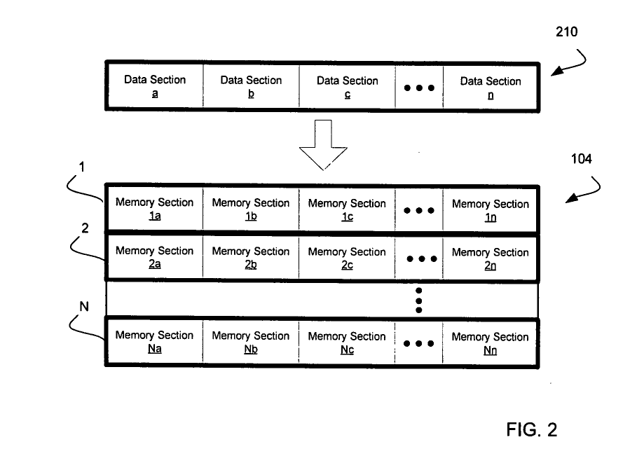

FIG. 2 shows an example of a memory 104 which has been logically divided into multiple blocks 1, 2, . . . N. For example, in one embodiment, each memory block 1, 2, . . . N may have approximately 4000 (4 kilobit (Kb)) bitcells in each memory block. Each bitcell when operational, that is, operating properly, is configured to store charge representing either a first logical bit value such as a logical one, for example, or a second logical bit value such as a logical zero, for example, which is different from the first logical bit value. In the illustrated embodiment, each bitcell stores a single data bit. However, it is appreciated that memory circuit defect correction in accordance with the present description is applicable to bitcells configured to store multiple data bits. It is further appreciated that the number of bitcells in each memory block may be greater or less than 4 Kb, depending upon the particular application.

In addition, in the illustrated embodiment, the number of bitcells in each memory block is the same or substantially the same. It is appreciated that in other embodiments, the number of bitcells in the various memory blocks may vary from memory block to memory block.

It is appreciated that each memory block 1, 2, . . . N, may have tens, a hundred or more defective bitcells, depending upon the particular memory 104 and the fabrication process used to fabricate the memory 104. In accordance with another aspect of the present description, each 4 Kb memory block 1, 2, . . . N may be further logically divided into 40 sections of memory, with 100 bitcells in each memory section for storing user data, a flip-flag data bit, and error correction code parity. Thus, the memory block 1, for example, may be logically divided into 40 memory sections represented by the memory sections 1a, 1b . . . 1n of FIG. 2. Similarly, the memory block 2, for example, may be logically divided into 40 memory sections represented by the memory sections 2a, 2b . . . 2n of FIG. 2. The memory block N, may similarly be logically divided into 40 memory sections represented by the memory sections Na, Nb . . . Nn of FIG. 2. It is appreciated that the size and number of the memory sections of each memory block, may vary, depending upon the application.

Although the memory 104 is described as being logically divided into memory blocks 1, 2, . . . N, it is appreciated that one or more of the memory blocks 1, 2, . . . N, may be physically divided as well from other memory blocks by segregating memory circuits within a die or placing the memory blocks on different dies, etc. Similarly, although the memory blocks 1, 2, . . . N, are described as being logically divided into memory sections, it is appreciated that one or more of the memory sections may be physically divided as well from other memory sections by segregating memory circuits within a die or placing the memory blocks on different dies, etc.

In accordance with the present description, it is recognized by that as a result of the subdivision of each block 1, 2, . . . N of memory 104 into sections of memory, most of the memory sections will have no defective bitcells or at most one defective bitcell. For example, if the memory block 1 has 100 defective bitcells, most of the 40 memory sections 1a, 1b, . . . 1n of the memory block 1 will have no defective bitcells or at most one defective bitcell, assuming a typical distribution of defective bitcells within the memory block 1.

For example, the memory section 1a of this example may be identified as having no defective bitcells. Thus, for those memory sections such as memory section 1a having no defective bitcells, the data transfer and storage operations will be free of errors caused by defective bitcells, since the memory sections do not have any defective bitcells.

In another example, the memory section 1b may be identified as having only a single defective bitcell. Thus, for those memory sections such as memory section 1b having a single defective bitcell, selective data flipping in accordance with the present description may be readily applied to eliminate a data transfer or storage error caused by the single defective bitcell. The memory sections of the memory block 1 having at most a single defective bitcell, may include the clear majority of memory sections 1a, 1b, . . . 1n of the memory block 1. For example, depending upon the distribution of defective bitcells within the memory block 1, the memory sections of the memory block 1 having at most a single defective bitcell, may include in one example, approximately 90% or more of the memory sections 1a, 1b, . . . 1n of the memory block 1. For such memory sections, errors due to defective bitcells do not occur or may be readily corrected. Accordingly, the overall error rate of the memory block 1 due to defective bitcells may be reduced.

In another example, the number of memory sections having two or more defective bitcells may be as low as 10 percent or less of the total number of memory sections 1a, 1b, . . . 1n of the memory block 1, depending upon the particular distribution of defective bitcells within the memory block 1. As explained in greater detail below, for those memory sections have two or more defective bitcells, selective data flipping in accordance with the present description may nonetheless be applied to reduce data transfer or storage errors caused by the defective bitcells. Accordingly, the overall error rate of the memory due to defective bitcells may be further reduced.

In another aspect of memory circuit defect correction in accordance with the present description, a block of data to be stored in a corresponding memory block such as one of the memory blocks 1, 2 . . . N, may be logically divided into a plurality of data bit sections, each data bit section to be written into and stored in an associated memory section of a block of memory logically divided into a plurality memory sections as described above. FIG. 2 shows an example of a data bit block 210 to be stored into one of the memory blocks 1, 2 . . . N. In the illustrated embodiment, the size of each data bit block 210 conforms to the size of the memory block into which it is to be stored. Thus, in one example, each data bit block 210 may have approximately 4000 (4 kilobit (Kb)) data bits to be stored in one of the memory blocks 1, 2, . . . N.

As set forth above, each 4 Kb data bit block 210 may be logically divided into 40 sections of data bits, with 100 data bits in each data bit section memory section for storing user data, and meta data including a flip-flag data bit, and other metadata such as error correction parity or cache metadata, for example. Thus, the data bit block 210, for example, may be logically divided into 40 data bit sections represented by the data bit sections a, b . . . n of FIG. 2.

It is appreciated that the number of data bits in each data bit block 210 or each data bit section a, b, n, may be greater or lesser depending upon the particular application. In addition, in the illustrated embodiment, the number of bits in each data bit block is the same or substantially the same, and the number of bits in each data bit section is the same or substantially the same. It is appreciated that in other embodiments, the number of bits in the various data bit blocks may vary from data bit block to data bit block, and the number of bits in the various data bit sections may vary from data bit section to data bit section.

Each data bit section is associated with a memory section. Thus if the data bit block 210 is to be stored in the memory block 1, for example, the data section a is stored in the associated memory section 1a, the data section b is stored in the associated memory section 1b, etc. As explained in greater detail below, in defective memory circuit correction in accordance with one aspect of the present description, for each data bit section and its associated memory section, the logical values of all the user data bits of the data bit section are selectively flipped, that is flipped, or not flipped, so that the logical value of a user data bit to be written into a defective bitcell matches the fixed read output of the defective bitcell of the memory section. As a result, errors due to defective bitcells may be reduced.

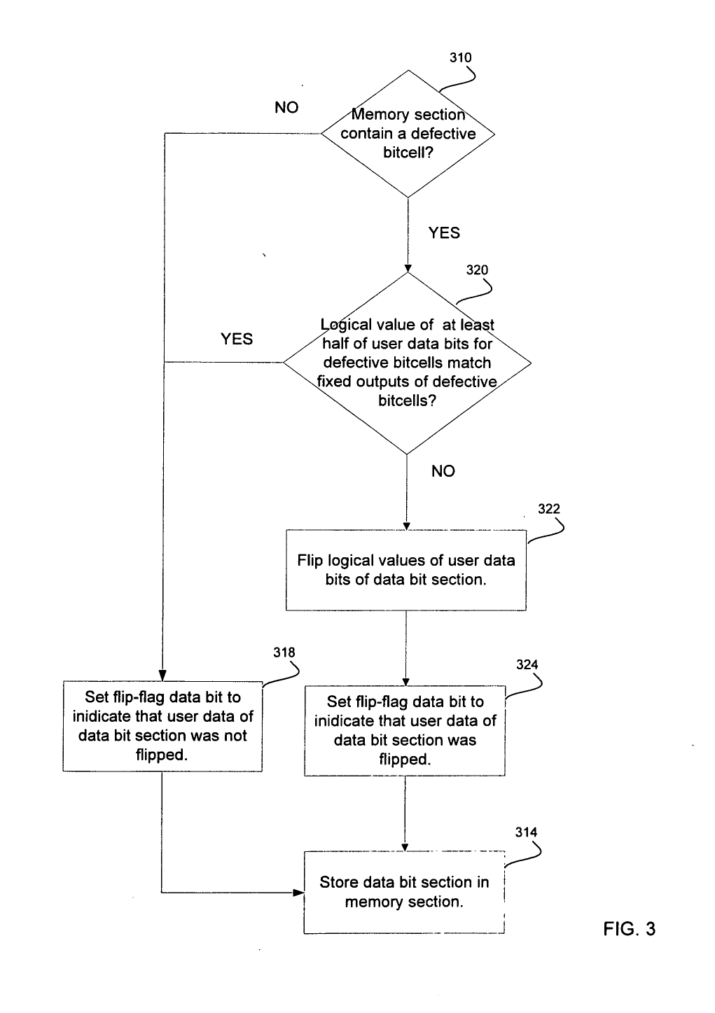

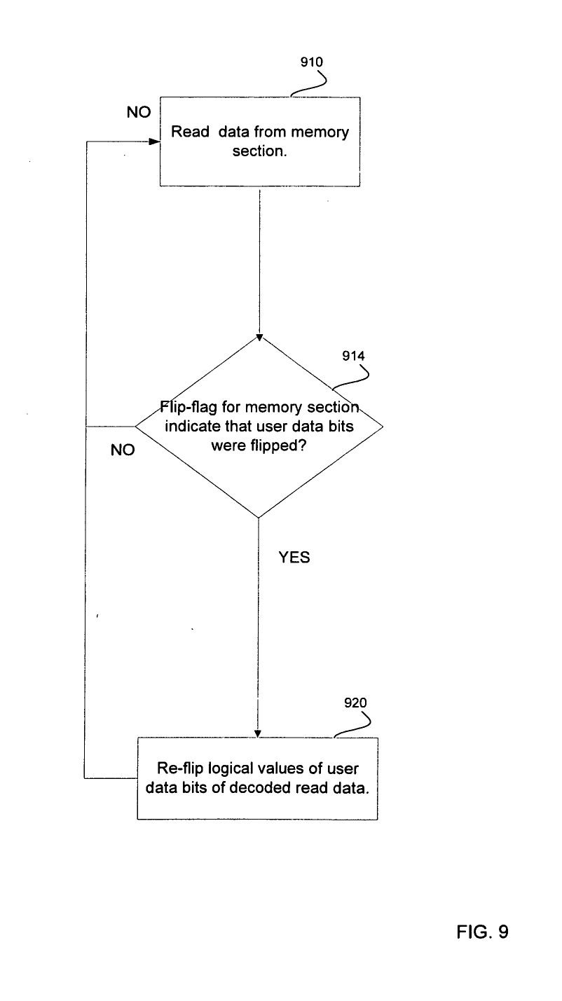

FIGS. 3 and 9 show examples of operations of the data transfer logic 108 (FIG. 1) and the memory circuit defect correction logic 110 of the memory controller 106. More specifically, FIG. 3 depicts operations to correct memory defects for a transfer of a data bit section to a target memory section addressed by the data transfer operation. FIG. 9 depicts operations to correct memory defects for a transfer of a data bit section from the target memory section in which it was stored. The data transfer logic 108 including the defect correction logic 110 are configured to perform the operations depicted in the figures and described herein, and may be implemented with software, hardware, firmware or combinations thereof including dedicated and programmable logic circuitry, and programmed processors, for example.

Referring to FIG. 3, in one operation, the memory circuit defect correction logic 110 determines (block 310, FIG. 3) whether the target memory section, such as the memory section 1a of FIG. 2, for example, addressed by the data transfer operation, contains a defective bitcell. In one embodiment, the presence of defective bitcells in a memory section may be made by test equipment or devices external to the system 100 at the time of manufacture of the memory 104. In another embodiment, the presence of defective bitcells in a memory section may be determined by test equipment or devices internal to the system 100 such as built-in test circuitry of the memory controller 106 at the time of manufacture of the system 100 or the memory 104. In another embodiment, the presence of defective bitcells in a memory section may be determined by built-in test circuit as the system 100 is being used by in regular operations of the system 100.

For each defective bitcell determined to be present in a memory section, data may be stored in a suitable data structure by the memory circuit defect correction logic 110 indicating which memory sections contain a defective bitcell, the bitcell address or location of each such defective bitcell and the type of each such defective bitcell. As previously mentioned, bitcell defects may be of different types such as an open circuit defect, for example, which has a first fixed read output such as a logical one value, for example, and a short circuit defect, for example, which has a different fixed read output such as a logical zero output, for example. One example of a suitable data structure is a map which maps the location or address and type of each defective bitcell of the memory.

If the memory circuit defect correction logic 110 determines (block 310, FIG. 3) that the target memory section, such as the memory section 1a of FIG. 2, for example, addressed by the data transfer operation, does not contain a defective bitcell, the data bit section may be stored (block 314) without flipping the logical values of the user data bits of the data bit section since no defective bitcell errors are expected because the target memory section lacks defective bitcells. Accordingly, a flip-flag may be set (block 318) by the defect correction logic 110, indicating that the user data of the data bit section was not flipped. In one embodiment, error correction code parity may be encoded by error correction code (ECC) logic 140 (FIG. 1) of the data transfer logic 108 of the memory controller 106 to facilitate error detection and correction. In one embodiment, the ECC parity may be stored outside the memory section storing the user data bits and the flip-flag bit as described above. In another embodiment, the ECC parity may be stored in the same memory section.

Conversely, if the memory circuit defect correction logic 110 determines (block 310, FIG. 3) that the target memory section addressed by the data transfer operation, does contain at least one defective bitcell, a determination (block 320) is made by the memory circuit defect correction logic 110 as to whether the logical value of at least half of the user data bits addressed to defective bitcells of the target memory section match the fixed outputs of the defective bitcells.

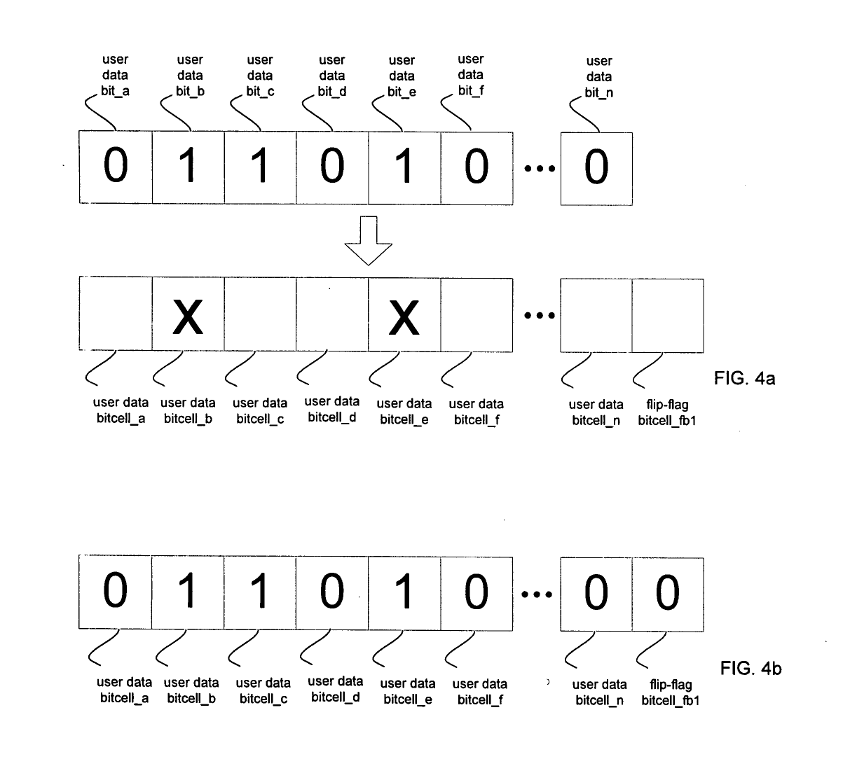

FIG. 4a shows an example of a portion of a target memory section having two defective bitcells in this example. The target memory section has a field of bitcells bitcell_a, bitcell_b, . . . bitcell_n, for storing user data bits, bit_a, bit_b, . . . bit_n, respectively, of a data bit section addressed to the target memory section. The target memory section further has a flip-flag bitcell, flip-flag bitcell_fb1, for storing a flip-flag bit. The bitcells of the target memory section for storing other metadata such as error correction parity or cache metadata have been omitted from FIG. 4a for sake of clarity.

In this example, the user data bitcells, bitcell_b and bitcell_e, both contain an open circuit type defect as indicated by the “X” in each bitcell. In this example, an open circuit type defect has a fixed read output corresponding to a logical one value, notwithstanding the logical value of any data attempted to be stored in such open circuit defective bitcells. However, in this example, the user data bits, user data bit_b and user data bit_e, of the user data bits bit_a, bit_b, . . . bit_n of a data bit section addressed to the target memory section, each have a logical one value in FIG. 4a. Accordingly, the logical one value of the user data bit_c and user data bit_e, both match the logical one fixed read output of the open circuit defective bitcells, bitcell_b and bitcell_e, respectively, addressed by the user data bit_b and user data bit_e, respectively. Accordingly, for the example of FIG. 4a, it is determined (block 320) by the memory circuit defect correction logic 110 that the logical value of at least half of the user data bits addressed to defective bitcells of the target memory section matches the fixed outputs of the defective bitcells. As a result, the user data bits of the data bit section may be stored (block 314) as shown in FIG. 4b without flipping the logical values of the user data bits of the data bit section. No defective bitcell errors are expected since the logical values of the bits addressed to the defective bitcells of the memory section, match the fixed read outputs of those defective bitcells. Accordingly, a flip-flag for the associated target memory section may be set (block 318) as indicated by the logical zero value stored in the flip-flag bitcell_fb1 of the target memory section, indicating that the user data of the data bit section stored in the target memory section, was not flipped in the target memory section. In one embodiment, error correction code parity may be encoded on the basis of the original (that is, not flipped) user data bits (FIG. 4b), by error correction code (ECC) logic 140 (FIG. 1) of the data transfer logic 108 of the memory controller 106 to facilitate error detection and correction. The ECC parity may be stored outside the memory section for the user data bits and the flip-flag bit (FIG. 4b) as described above.

FIGS. 4a, 4b are directed to an example in which the target memory section has two open circuit defect bitcells and the user data bits addressed to those two defective bitcells both match the fixed read outputs of the defective bitcells. It is appreciated that defective memory correction in accordance with the present description may operate in a substantially similar fashion in an example in which the target memory section has a single open circuit defect bitcell and the user data bit addressed to the single defective bitcell matches the fixed read output of the defective bitcell.

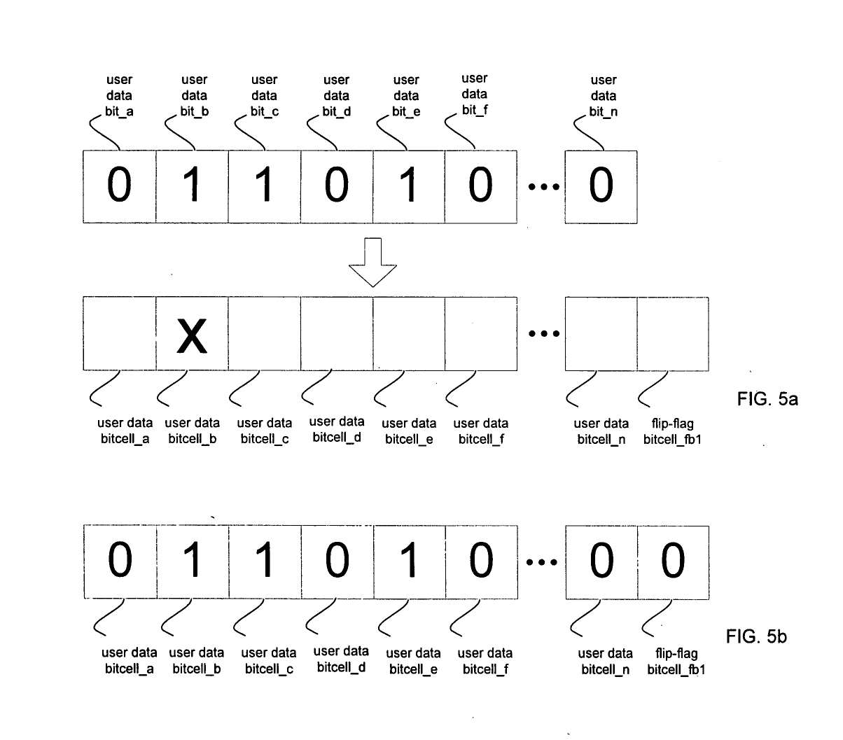

For example, FIG. 5a shows an example of a portion of a target memory section having a single open circuit defective bitcell, bitcell_b as indicated by the “X” in the bitcell_b1 in this example. As previously mentioned, in this example, an open circuit type defect has a fixed read output corresponding to a logical one value, notwithstanding the logical value of any data attempted to be stored in such open circuit defective bitcells. Accordingly, the open circuit defective bitcell_b has a fixed read output of logical one, in this example. However, in this example, the user data bit, user data bit_b of the user data bits bit_a, bit_b, . . . bit_n of a data bit section addressed to the target memory section, also has a logical one value in FIG. 5a.

Accordingly, the logical value one of the user data bit_b matches the logical one fixed read output of the open circuit defective bitcell_b addressed by the user data bit_b. Thus, for the example of FIG. 5a, it is determined (block 320) by the memory circuit defect correction logic 110 that in this example, the logical value of at least half of the user data bits addressed to defective bitcells of the target memory section again matches the fixed outputs of the defective bitcells. As a result, the user data bits of the data bit section may be stored (block 314) as shown in FIG. 5b without flipping the logical values of the user data bits of the data bit section since no defective bitcell errors are expected since the logical values of the bits addressed to the defective bitcells of the memory section, match the fixed read outputs of those defective bitcells.

Accordingly, a flip-flag for the associated target memory section may be set (block 318) as indicated by the logical zero value stored in the flip-flag bitcell_fb1 of the target memory section, indicating that the user data of the data bit section was not flipped in the target memory section. In one embodiment, error correction code parity may be encoded on the basis of the original (that is, not flipped) user data bits (FIG. 5b), by error correction code (ECC) logic 140 (FIG. 1) of the data transfer logic 108 of the memory controller 106 to facilitate error detection and correction. The ECC parity may be stored outside the memory section for the original user data bits and the flip-flag bit (FIG. 5b) as described above. It is appreciated that defective memory correction in accordance with the present description may operate in a substantially similar fashion in example in which the target memory section has multiple such as three or more open circuit defect bitcells and the user data bits addressed to the multiple defective bitcells all match the fixed read output of the defective bitcell.

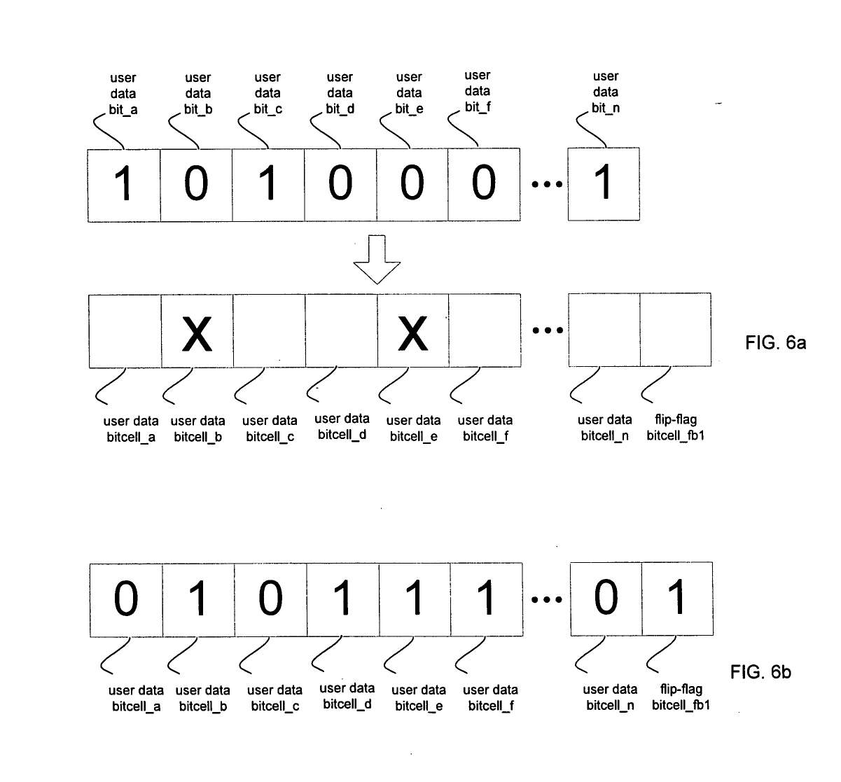

FIG. 6a shows an example of a portion of a target memory section having two defective bitcells, bitcell_b and bitcell_e, in this example. More specifically, the user data bitcells, bitcell_b and bitcell_e, both contain an open circuit type defect as indicated by the “X” in each bitcell. Again, in this example, an open circuit type defect has a fixed read output corresponding to a logical one value, notwithstanding the logical value of any data attempted to be stored in such open circuit defective bitcells. However, in this example, the user data bits, user data bit_b and user data bit_e, of the user data bits bit_a, bit_b, . . . bit_n of a data bit section addressed to the target memory section, each have a logical zero value in FIG. 6a.

Accordingly, the logical zero value of the user data bit_c and user data bit_e, both do not match the logical one fixed read output of the open circuit defective bitcells, bitcell_b and bitcell_e, respectively, addressed by the user data bit_b and user data bit_e, respectively. Thus, for the example of FIG. 6a, it is determined (block 320) by the memory circuit defect correction logic 110 that the logical value of at least half of the user data bits addressed to defective bitcells of the target memory section, do not match the fixed outputs of the defective bitcells. As a result, the user data bits of the data bit section may be flipped (block 322, FIG. 3) and stored (block 314) as shown in FIG. 6b with the logical value of each user data bit of the data, bit section in the flipped state. Again, no defective bitcell errors are expected since the logical values of the bits addressed to the defective bitcells of the memory section, have been flipped to match the fixed read outputs of those defective bitcells.

Accordingly, a flip-flag for the associated target memory section may be set (block 324) as indicated by the logical one value stored in the flip-flag bitcell_fb1 of the target memory section, indicating that the user data of the data bit section stored in the target memory section, has been flipped in the target memory section. In one embodiment, error correction code parity may be encoded on the basis of the flipped user data bits (FIG. 6b) by error correction code (ECC) logic 140 (FIG. 1) of the data transfer logic 108 of the memory controller 106 to facilitate error detection and correction. In another embodiment, error correction code parity may be encoded on the basis of the original unflipped user data bits (FIG. 6a) by error correction code (ECC) logic 140 (FIG. 1) of the data transfer logic 108 of the memory controller 106 to facilitate error detection and correction. The ECC parity may be stored outside the memory section for the flipped user data bits (FIG. 6b) and the flip-flag bit as described above.

FIGS. 6a, 6b are directed to an example in which the target memory section has two open circuit defect bitcells and the user data bits addressed to those two defective bitcells both do not match the fixed read outputs of the defective bitcells. It is appreciated that defective memory correction in accordance with the present description may operate in a substantially similar fashion in an example in which the target memory section has a single open circuit defect bitcell and the user data bit addressed to the single defective bitcell does not match the fixed read output of the defective bitcell.

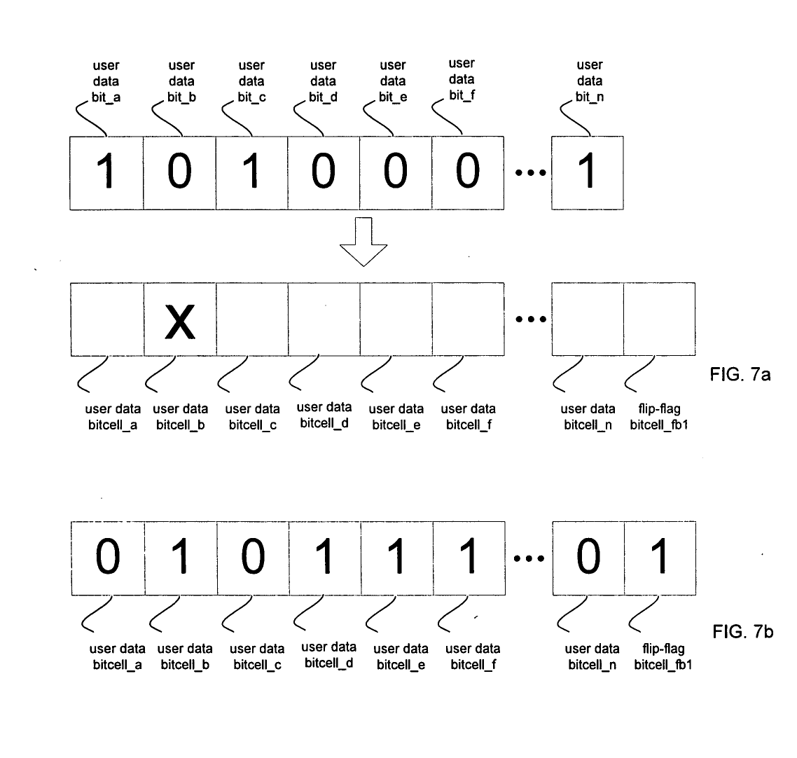

For example, FIG. 7a shows an example of a portion of a target memory section having a single open circuit defective bitcell, bitcell_b as indicated by the “X” in the bitcell_b1 in this example. As previously mentioned, in this example, an open circuit type defect has a fixed read output corresponding to a logical one value, notwithstanding the logical value of any data attempted to be stored in such open circuit defective bitcells. Accordingly, the open circuit defective bitcell_b has a fixed read output of logical one, in this example. However, in this example, the user data bit, user data bit_b of the user data bits bit_a, bit_b, . . . bit_n of a data bit section addressed to the target memory section, has a logical zero value in FIG. 7a.

Accordingly, the logical value zero of the user data bit_b does not match the logical one fixed read output of the open circuit defective bitcell_b addressed by the user data bit_b. Thus, for the example of FIG. 7a, it is determined (block 320) by the memory circuit defect correction logic 110 that in this example, the logical value of at least half of the user data bits addressed to defective bitcells of the target memory section does not match the fixed outputs of the defective bitcells. As a result, the user data bits of the data bit section may be flipped (block 322, FIG. 3) and stored (block 314) as shown in FIG. 7b in which the logical values of the user data bits of the data bit section have been flipped. Again, no defective bitcell errors are expected since the logical value of the bit addressed to the defective bitcell of the memory section, has been flipped to match the fixed read output of the defective bitcell.

Accordingly, a flip-flag for the associated target memory section may be set (block 324) as indicated by the logical one value stored in the flip-flag bitcell_fb1 of the target memory section, indicating that the user data of the data bit section was flipped in the target memory section. In one embodiment, error correction code parity may be encoded on the basis of the flipped user data bits (FIG. 7b) by error correction code (ECC) logic 140 (FIG. 1) of the data transfer logic 108 of the memory controller 106 to facilitate error detection and correction. In another embodiment, error correction code parity may be encoded on the basis of the original unflipped user data bits (FIG. 7a) by error correction code (ECC) logic 140 (FIG. 1) of the data transfer logic 108 of the memory controller 106 to facilitate error detection and correction. The ECC parity may be stored outside the memory section for the flipped user data bits (FIG. 7b) and the flip-flag bit as described above.

It is appreciated that defective memory correction in accordance with the present description may operate in a substantially similar fashion in an example in which the target memory section has multiple such as three or more open circuit defect bitcells and the user data bits addressed to the multiple defective bitcell all do not match the fixed read output of the defective bitcell.

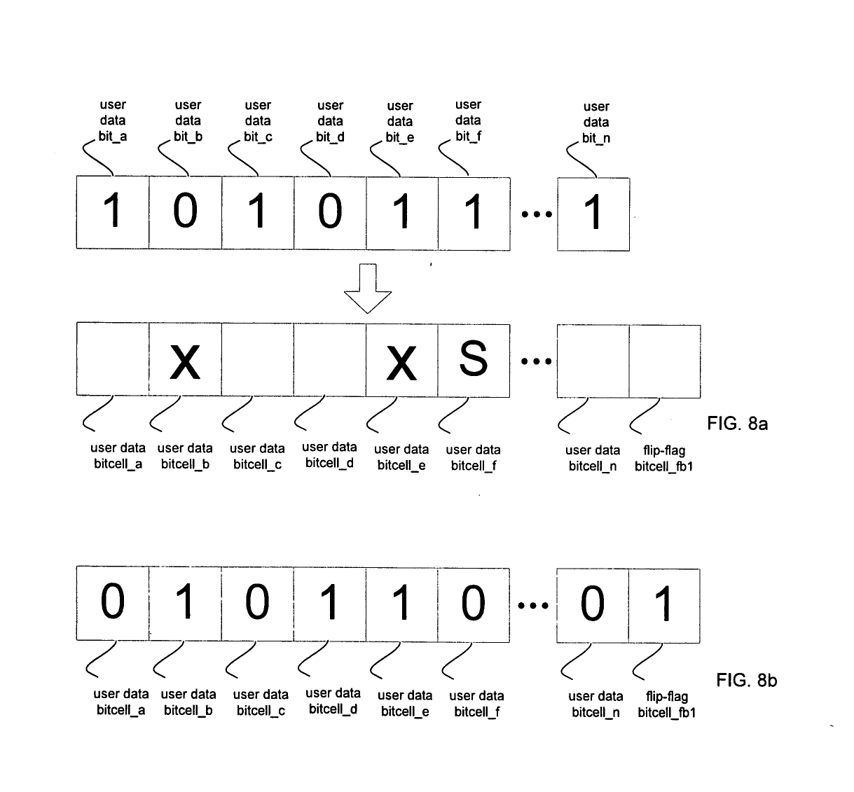

FIG. 8a shows an example of a portion of a target memory section having three defective bitcells, bitcell_b, bitcell_e and bitcell_f, in this example. More specifically, the user data bitcells, bitcell_b and bitcell_e, both contain an open circuit type defect as indicated by the “X” in each bitcell. Again, in this example, an open circuit type defect has a fixed read output corresponding to a logical one value, notwithstanding the logical value of any data attempted to be stored in such open circuit defective bitcells. The user data bitcell_f contains a short circuit type defect as indicated by the “S” in the bitcell. Again, in this example, a short circuit type defect has a fixed read output corresponding to a logical zero value, notwithstanding the logical value of any data attempted to be stored in such open circuit defective bitcells.

However, in this example, the user data bits, user data bit_b and user data bit_e, of the user data bits bit_a, bit_b, . . . bit_n of a data bit section addressed to the target memory section, have a logical zero value and a logical one value, respectively, in FIG. 8a. Accordingly, the logical zero value of the user data bit_c does not match the logical one fixed read output of the open circuit defective bitcell_b, whereas the logical one value of the user data bit_e does match the logical one fixed read output of the open circuit defective bitcell_e. Further, the logical one value of the user data bit_f does not match the logical zero fixed read output of the short circuit defective bitcell_f.

Accordingly, for the example of FIG. 8a, it is determined (block 320) by the memory circuit defect correction logic 110 that the logical values of at least half of the user data bits addressed to defective bitcells of the target memory section, do not match the fixed outputs of the defective bitcells. As a result, the user data bits of the data bit section may be flipped (block 322, FIG. 3) and stored (block 314) as shown in FIG. 6b with the logical value of each user data bit of the data bit section in the flipped state. Again, no defective bitcell errors are expected for the bitcells bitcell_b and bitcell_f since the logical values of the bits addressed to the defective bitcells of the memory section, have been flipped to match the fixed read outputs of those defective bitcells. Accordingly, a flip-flag for the associated target memory section may be set (block 324) as indicated by the logical one value stored in the flip-flag bitcell_fb1 of the target memory section, indicating that the user data of the data bit section stored in the target memory section, has been flipped in the target memory section.

Conversely, a defective bitcell error is expected for the bitcell_e since the logical value of the bit_e addressed to the defective bitcell_e of the memory section, has been flipped from a logical one value (FIG. 8a) to a logical zero value and a logical zero value will not match the fixed logical one read output of the open circuit defective bitcell_e as shown in FIG. 8b. Nevertheless, the number of potential errors due to defective bitcells has been reduced to a single error due to defective bitcells, for a memory employing memory circuit defect correction in accordance with the present description.

In one embodiment, error correction code parity may be encoded on the basis of the flipped user data bits (FIG. 8b) by error correction code (ECC) logic 140 (FIG. 1) of the data transfer logic 108 of the memory controller 106 to facilitate error detection and correction. In another embodiment, error correction code parity may be encoded on the basis of the original unflipped user data bits (FIG. 8a) by error correction code (ECC) logic 140 (FIG. 1) of the data transfer logic 108 of the memory controller 106 to facilitate error detection and correction. The ECC parity may be stored outside the memory section for the flipped user data bits (FIG. 8b) and the flip-flag bit as described above.

It is appreciated that defective memory correction in accordance with the present description may operate in a substantially similar fashion in an example in which the target memory section has two defective bitcells, either open circuit or short circuit, and the user data bits addressed to the multiple defective bitcell all do not match the fixed read outputs of the two defective bitcells. Thus, one bit, that is, one half of the user data bits addressed to the two defective bitcells matches the fixed read output of one defective bitcell, and one bit, that is, one half of the user data bits addressed to the two defective bitcells do not match the fixed read output of the other defective bitcell. In such case, the user data bits of the data bit section may all be flipped or all not flipped, and the flip-flag of the memory section set accordingly, to reduce errors due to the defective bitcells.

Thus, it is seen that defective memory correction in accordance with the present description may eliminate errors due to defective bitcells in those examples in which the user data bits addressed to the defective bitcells of a memory section are determined to either all match or all not match, the fixed read outputs of the defective bitcells, by selectively flipping the user data bits addressed to the memory section, as a function of the match or not match determination. Similarly, it is seen that defective memory correction in accordance with the present description may reduce errors due to defective bitcells in those examples in which it is determined that at least half the user data bits addressed to the defective bitcells of a memory section either match or do not match, the fixed read outputs of the defective bitcells, by selectively flipping the user data bits addressed to the memory section, as a function of the match or not match determination. The flip-flag of the memory section is correspondingly set to indicate whether the user bits were flipped or not.

FIG. 9 depicts operations of the data transfer logic 108 (FIG. 1) and the memory circuit defect correction logic 110 of the memory controller 106, to transfer a data bit section from the target memory section in which it was stored. In one operation, read data may be read (block 910, FIG. 9) from a memory section. In one embodiment, the data stored in the target memory section may have been ECC encoded as described above. Accordingly, the encoded read data from the target memory section may be decoded by error correction code (ECC) logic 140 (FIG. 1) of the data transfer logic 108 of the memory controller 106 to facilitate error detection and correction. Thus, if the ECC logic 140 detects errors in the decoded read data from the memory section, the errors may be corrected by the ECC logic 140, depending upon the robustness of the ECC encoding and the severity of the detected errors.

Once the read data has been decoded and any detected errors corrected by the error correction logic 140, a determination may be made as to whether (block 914, FIG. 9) the flip-flag read from the memory section indicates that user data bits of the read data have been flipped. In the illustrated embodiment, a flip-flag bit may be read from the flip-flag bitcell_fb1 (FIGS. 4a-8b) in which a logical zero value indicates that the user data bits stored in the memory section have not been flipped and a logical one value indicates that the user data bits stored in the memory section have been flipped. It is appreciated that in other embodiments, a flip-flag bit having a logical one value indicates that the user data bits stored in the memory section have not been flipped and a logical zero value indicates that the user data bits stored in the memory section have been flipped.

If the user data bits have been flipped, the user data bits may be re-flipped (block 920, FIG. 9) to restore the logical values of each of the user data bits to their original values, and the encoded read data from another memory section may be obtained (block 910). Conversely, if it is determined by inspecting the flip-flag (block 914) that the user data bits have not been flipped, the re-flipping of the user data bits may be bypassed since the logical values of each of the user data bits are already at their original values, and encoded read data from another memory section may be obtained (block 910).

In one embodiment, write data is ECC encoded to generate ECC parity and then the user data is selectively flipped, as appropriate, before storing the write data in in a memory section as discussed above. Conversely, user data of encoded read data is selectively re-flipped, as appropriate as discussed above, and then decoded. It is appreciated that in other embodiments, these operations may be performed in other orders of operations. For example, user data of write data may be selectively flipped as appropriate and then ECC encoded to generate ECC parity for storing in an appropriate memory section. Conversely, encoded read data is decoded and then user data bits of decoded read data may be selectively re-flipped as appropriate. Other sequences of operations may be suitable, depending upon the particular application.

One example of a suitable error correction code is a low-density parity-check code (LDPC) which utilizes soft reads of bitcells which compare the read threshold voltage of a bitcell to various voltage levels and assigns a confidence level to the logical value determined by the soft read. For example, a read threshold voltage which is close to a default read reference voltage, may be assigned a low confidence level whereas a read threshold voltage which is substantially above or below the default read reference voltage may be assigned a logical value at a relatively high confidence level. The LDPC detects and corrects errors as a function of the confidence level of the bits read from the memory.

It is appreciated herein that bits read from bitcells having an open circuit or short circuit defect may not only provide an erroneous logical value output but may also be erroneously assigned a high confidence level. Thus, open circuit and short circuit defects can seriously degrade the performance of LDPC error detection and correction. Memory circuit defect correction in accordance with the present description, by reducing or eliminating errors caused by open circuit or short circuit bitcell defects, that the overall ECC data correction performance by a correction scheme such as LDPC error correction, for example, may be enhanced.

Accordingly, memory circuit defect correction in accordance with the present description may be applied to reduce or eliminate errors caused by open circuit or short circuit bitcell defects in soft bit read operations. It is appreciated that memory circuit defect correction in accordance with the present description may be applied to reduce or eliminate errors caused by open circuit or short circuit bitcell defects in hard bit read operations which do not utilize soft bit read techniques.

It is further appreciated that other types of error detection and correction codes may be employed with memory circuit defect correction in accordance with the present description. For example, both block and convolutional codes may be suitable for memory circuit defect correction in accordance with the present description. Reed-Solomon error correction code is a block code which encodes blocks of data in symbols to facilitate error detection and correction.

Also, both systematic and nonsystematic codes may be for suitable memory circuit defect correction in accordance with the present description. In a systematic scheme, an encoder attaches to the original write data a number of check bits (such as parity, for example), which are derived from the data bits by an appropriate deterministic algorithm. In a system that uses a non-systematic code, the original message is transformed into an encoded message that typically has at least as many bits as the original message. Additional examples of codes which may be suitable are concatenated codes, recursive codes, non-recursive codes, repetition codes, Hamming codes, multidimensional parity-check codes, turbo codes, low-density parity-check codes (LDPC), etc.

### EXAMPLES

The following examples pertain to further embodiments.

Example 1 is an apparatus, comprising:

a memory having a block of bitcells logically divided into a plurality of memory sections, each memory section having a plurality of bitcells which include at least one of operational bitcells and both operational bitcells and a defective bitcell of a first type, each operational bitcell configured to store charge representing either a first logical bit value or a second logical bit value different from the first logical bit value, and each defective bitcell of the first type having a fixed read output at the first logical value; and

a memory controller comprising data transfer logic configured to store data into and read data from the memory, said data transfer logic including memory circuit defect correction logic configured to logically divide a block of data bits including user data bits, into a plurality of data bit sections, each data bit section to be written into an associated memory section of the block of the memory and, for each data bit section and its associated memory section, to selectively flip the logical values of all the user data bits of the data bit section so that the logical value of a user data bit to be written into a defective bitcell of a first type, matches the fixed read output at the first logical value.

In Example 2, the subject matter of Examples 1-9 (excluding the present Example) can optionally include wherein each memory section further has a plurality of bitcells which include at least one of said operational bitcells and both said operational bitcells and a defective bitcell of a second type, each defective bitcell of the second type having a fixed read output at the second logical value, and wherein the memory circuit defect correction logic is further configured to, for each data bit section and its associated memory section, selectively flip the logical values of all the user data bits of the data bit section so that the logical value of a user data bit to be written into a defective bitcell of the second type matches the fixed read output at the second logical value.

In Example 3, the subject matter of Examples 1-9 (excluding the present Example) can optionally include wherein each memory section further has a flip-flag bitcell, the data transfer logic is further configured to store each data bit section into its associated memory section, and the memory circuit defect correction logic is further configured, for each memory section, to set a flip-flag in the flip-flag bitcell for the associated memory section to indicate whether the logical values of all the user data bits of the data bit section stored in the associated memory section were flipped.

In Example 4, the subject matter of Examples 1-9 (excluding the present Example) can optionally include wherein the data transfer logic is further configured to read the data bit section stored in each memory section, and the memory circuit defect correction logic is further configured to selectively re-flip the logical values of all the user data bits of the data bit section read from a memory section if the flip-flag bitcell for the associated memory section indicates that the logical values of all the user data bits of the data bit section stored in the associated memory section were flipped.

In Example 5, the subject matter of Examples 1-9 (excluding the present Example) can optionally include wherein the memory circuit defect correction logic is further configured to, for each memory section having at least one defective bitcell, identify the location of each such defective bitcell in the memory section.

In Example 6, the subject matter of Examples 1-9 (excluding the present Example) can optionally include wherein the memory circuit defect correction logic is further configured to determine whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

In Example 7, the subject matter of Examples 1-9 (excluding the present Example) can optionally include wherein the memory circuit defect correction logic is further configured so that the setting a flip-flag includes setting the logical value of the flip-flag bitcell for the associated memory section.

In Example 8, the subject matter of Examples 1-9 (excluding the present Example) can optionally include wherein each block of data bits includes at least 100 bits of data, wherein the memory circuit defect correction logic is further configured so that the logically dividing the block of data bits includes logically dividing the block of data bits into at least ten of said data bit sections, wherein each data bit section has at least a ten data bits and wherein the block of memory has at least ten of said memory sections.

In Example 9, the subject matter of Examples 1-9 (excluding the present Example) can optionally include wherein the memory controller further has error correction code logic configured to encode the user data bits of each data bit section in an error correction code, and to decode the encoded read data using the error correction code.

Example 10 is a method, comprising:

logically dividing a block of data bits including user data bits, into a plurality of data bit sections, each data bit section to be written into an associated memory section of a block of memory logically divided into a plurality memory sections, each memory section having a plurality of operational bitcells, each operational bitcell for storing charge representing either a first logical bit value or a second logical bit value different from the first logical bit value; and

for each data bit section and its associated memory section, selectively flipping the logical values of all the user data bits of the data bit section so that the logical value of a user data bit to be written into a defective bitcell of a first type identified as having a fixed read output at the first logical value, matches the fixed read output at the first logical value.

In Example 11, the subject matter of Examples 10-17 (excluding the present Example) can optionally include, for each data bit section and its associated memory section, selectively flipping the logical values of all the user data bits of the data bit section so that the logical value of a user data bit to be written into a defective bitcell of a second type identified as having a fixed read output at the second logical value, matches the fixed read output at the second logical value.

In Example 12, the subject matter of Examples 10-17 (excluding the present Example) can optionally include:

storing each data bit section into its associated memory section; and

for each memory section, setting a flip-flag for the associated memory section to indicate whether the logical values of all the user data bits of the data bit section stored in the associated memory section were flipped.

In Example 13, the subject matter of Examples 10-17 (excluding the present Example) can optionally include:

reading the user data bit section stored in each memory section; and

selectively re-flipping the logical values of all the user data bits of the data bit section read from a memory section if the flip-flag for the associated memory section indicates that the logical values of all the user data bits of the data bit section stored in the associated memory section were flipped.

In Example 14, the subject matter of Examples 10-17 (excluding the present Example) can optionally include, for each memory section having at least one defective bitcell, identifying the location of each such defective bitcell in the memory section.

In Example 15, the subject matter of Examples 10-17 (excluding the present Example) can optionally include wherein the selective flipping includes determining whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

In Example 16, the subject matter of Examples 10-17 (excluding the present Example) can optionally include wherein the setting a flip-flag includes setting the logical value of a bitcell for the associated memory section.

In Example 17, the subject matter of Examples 10-17 (excluding the present Example) can optionally include wherein each block of data bits includes at least 100 bits of data, wherein the logically dividing the block of data bits includes logically dividing the block of data bits into at least ten of said data bit sections, wherein each data bit section has at least ten data bits and wherein the block of memory has at least a hundred of said memory sections.

Example 18 is a system for use with a display, comprising:

a processor;

a video controller configured to control the display in response to the processor;

a memory having a block of bitcells logically divided into a plurality of memory sections, each memory section having a plurality of bitcells which include at least one of operational bitcells and both operational bitcells and a defective bitcell of a first type, each operational bitcell configured to store charge representing either a first logical bit value or a second logical bit value different from the first logical bit value, and each defective bitcell of the first type having a fixed read output at the first logical value; and

a memory controller comprising data transfer logic configured to store data into and read data from the memory, said data transfer logic including memory circuit defect correction logic configured to logically divide a block of data bits including user data bits, into a plurality of data bit sections, each data bit section to be written into an associated memory section of the block of the memory and, for each data bit section and its associated memory section, to selectively flip the logical values of all the user data bits of the data bit section so that the logical value of a user data bit to be written into a defective bitcell of a first type, matches the fixed read output at the first logical value.

In Example 19, the subject matter of Examples 18-25 (excluding the present Example) can optionally include wherein each memory section further has a plurality of bitcells which include at least one of said operational bitcells and both said operational bitcells and a defective bitcell of a second type, each defective bitcell of the second type having a fixed read output at the second logical value, and wherein the memory circuit defect correction logic is further configured to, for each data bit section and its associated memory section, selectively flip the logical values of all the user data bits of the data bit section so that the logical value of a user data bit to be written into a defective bitcell of the second type matches the fixed read output at the second logical value.

In Example 20, the subject matter of Examples 18-25 (excluding the present Example) can optionally include wherein each memory section further has a flip-flag bitcell, the data transfer logic is further configured to store each data bit section into its associated memory section, and the memory circuit defect correction logic is further configured, for each memory section, to set a flip-flag in the flip-flag bitcell for the associated memory section to indicate whether the logical values of all the user data bits of the data bit section stored in the associated memory section were flipped.

In Example 21, the subject matter of Examples 18-25 (excluding the present Example) can optionally include wherein the data transfer logic is further configured to read the data bit section stored in each memory section, and the memory circuit defect correction logic is further configured to selectively re-flip the logical values of all the user data bits of the data bit section read from a memory section if the flip-flag bitcell for the associated memory section indicates that the logical values of all the user data bits of the data bit section stored in the associated memory section were flipped.

In Example 22, the subject matter of Examples 18-25 (excluding the present Example) can optionally include wherein the memory circuit defect correction logic is further configured to, for each memory section having at least one defective bitcell, identify the location of each such defective bitcell in the memory section.

In Example 23, the subject matter of Examples 18-25 (excluding the present Example) can optionally include wherein the memory circuit defect correction logic is further configured to determine whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

In Example 24, the subject matter of Examples 18-25 (excluding the present Example) can optionally include wherein each block of data bits includes at least 100 bits of data, wherein the memory circuit defect correction logic is further configured so that the logically dividing the block of data bits includes logically dividing the block of data bits into at least ten of said data bit sections, wherein each data bit section has at least ten data bits and wherein the block of memory has at least a hundred of said memory sections.

In Example 25, the subject matter of Examples 18-25 (excluding the present Example) can optionally include wherein the memory controller further has error correction code logic configured to encode the user data bits of each data bit section in an error correction code, and to decode the encoded read data using the error correction code.

In Example 26, the subject matter of Examples 10-17 can optionally include at least one of the following additional operations:

(1) for each data bit section and its associated memory section, selectively flipping the logical values of all the user data bits of the data bit section so that the logical value of a user data bit to be written into a defective bitcell of a second type identified as having a fixed read output at the second logical value, matches the fixed read output at the second logical value;

(2)

storing each data bit section into its associated memory section; and

for each memory section, setting a flip-flag for the associated memory section to indicate whether the logical values of all the user data bits of the data bit section stored in the associated memory section were flipped;

(3)

reading the user data bit section stored in each memory section; and

selectively re-flipping the logical values of all the user data bits of the data bit section read from a memory section if the flip-flag for the associated memory section indicates that the logical values of all the user data bits of the data bit section stored in the associated memory section were flipped;

(4) for each memory section having at least one defective bitcell, identifying the location of each such defective bitcell in the memory section;

(5) wherein the selective flipping includes determining whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value;

(6) wherein the setting a flip-flag includes setting the logical value of a bitcell for the associated memory section; and

(7) wherein each block of data bits includes at least 100 bits of data, wherein the logically dividing the block of data bits includes logically dividing the block of data bits into at least ten of said data bit sections, wherein each data bit section has at least ten data bits and wherein the block of memory has at least a hundred of said memory sections.

Example 27 is an apparatus, comprising:

a memory having a block of bitcells logically divided into a plurality of memory sections, each memory section having a plurality of bitcells which include at least one of operational bitcells and both operational bitcells and a defective bitcell of a first type, each operational bitcell configured to store charge representing either a first logical bit value or a second logical bit value different from the first logical bit value, and each defective bitcell of the first type having a fixed read output at the first logical value; and

a memory controller comprising data transfer means for storing data into and reading data from the memory, said data transfer means including memory circuit defect correction means for logically dividing a block of data bits including user data bits, into a plurality of data bit sections, each data bit section to be written into an associated memory section of the block of the memory and, for each data bit section and its associated memory section, for selectively flipping the logical values of all the user data bits of the data bit section so that the logical value of a user data bit to be written into a defective bitcell of a first type, matches the fixed read output at the first logical value.

In Example 28, the subject matter of Examples 27-36 (excluding the present Example) can optionally include wherein each memory section further has a plurality of bitcells which include at least one of said operational bitcells and both said operational bitcells and a defective bitcell of a second type, each defective bitcell of the second type having a fixed read output at the second logical value, and wherein the memory circuit defect correction means is further configured to, for each data bit section and its associated memory section, selectively flip the logical values of all the user data bits of the data bit section so that the logical value of a user data bit to be written into a defective bitcell of the second type matches the fixed read output at the second logical value.

In Example 29, the subject matter of Examples 27-36 (excluding the present Example) can optionally include wherein each memory section further has a flip-flag bitcell, the data transfer means is further configured to store each data bit section into its associated memory section, and the memory circuit defect correction means is further configured, for each memory section, setting a flip-flag in the flip-flag bitcell for the associated memory section to indicate whether the logical values of all the user data bits of the data bit section stored in the associated memory section were flipped.

In Example 30, the subject matter of Examples 27-36 (excluding the present Example) can optionally include wherein the data transfer means is further configured to read the data bit section stored in each memory section, and the memory circuit defect correction means is further configured to selectively re-flip the logical values of all the user data bits of the data bit section read from a memory section if the flip-flag bitcell for the associated memory section indicates that the logical values of all the user data bits of the data bit section stored in the associated memory section were flipped.

In Example 31, the subject matter of Examples 27-36 (excluding the present Example) can optionally include wherein the memory circuit defect correction means is further configured to, for each memory section having at least one defective bitcell, identify the location of each such defective bitcell in the memory section.

In Example 32, the subject matter of Examples 27-36 (excluding the present Example) can optionally include wherein the memory circuit defect correction means is further configured to determine whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

In Example 33, the subject matter of Examples 27-36 (excluding the present Example) can optionally include wherein the memory circuit defect correction means is further configured so that the setting a flip-flag includes setting the logical value of the flip-flag bitcell for the associated memory section.

In Example 34, the subject matter of Examples 27-36 (excluding the present Example) can optionally include wherein each block of data bits includes at least 100 bits of data, wherein the memory circuit defect correction means is further configured so that the logically dividing the block of data bits includes logically dividing the block of data bits into at least ten of said data bit sections, wherein each data bit section has at least ten data bits and wherein the block of memory has at least a hundred of said memory sections.

In Example 35, the subject matter of Examples 27-36 (excluding the present Example) can optionally include wherein the memory controller further has error correction code means for encoding the user data bits of each data bit section in an error correction code, and to decode the encoded read data using the error correction code.

In Example 36, the subject matter of Examples 27-36 (excluding the present Example) can optionally include, for use with a display:

a processor; and

video controller means for controlling the display in response to the processor.

In Example 37, the subject matter of Examples 1-9 can optionally include, for use with a display:

a processor; and

a video controller configured to control the display in response to the processor.

Example 38 is an apparatus comprising means to perform a method as claimed in any preceding claim.

Example 39 is a machine-readable storage including machine-readable instructions, when executed, to implement a method or realize an apparatus or system as set forth in any preceding example.

The described operations may be implemented as a method, apparatus or computer program product using standard programming and/or engineering techniques to produce software, firmware, hardware, or any combination thereof. The described operations may be implemented as computer program code maintained in a “computer readable storage medium”, where a processor may read and execute the code from the computer storage readable medium. The computer readable storage medium includes at least one of electronic circuitry, storage materials, inorganic materials, organic materials, biological materials, a casing, a housing, a coating, and hardware. A computer readable storage medium may comprise, but is not limited to, a magnetic storage medium (e.g., hard disk drives, floppy disks, tape, etc.), optical storage (CD-ROMs, DVDs, optical disks, etc.), volatile and non-volatile memory devices (e.g., EEPROMs, ROMs, PROMs, RAMs, DRAMs, SRAMs, Flash Memory, firmware, programmable logic, etc.), Solid State Devices (SSD), etc. The code implementing the described operations may further be implemented in hardware logic implemented in a hardware device (e.g., an integrated circuit chip, Programmable Gate Array (PGA), Application Specific Integrated Circuit (ASIC), etc.). Still further, the code implementing the described operations may be implemented in “transmission signals”, where transmission signals may propagate through space or through a transmission media, such as an optical fiber, copper wire, etc. The transmission signals in which the code or logic is encoded may further comprise a wireless signal, satellite transmission, radio waves, infrared signals, Bluetooth, etc. The program code embedded on a computer readable storage medium may be transmitted as transmission signals from a transmitting station or computer to a receiving station or computer. A computer readable storage medium is not comprised solely of transmissions signals. Those skilled in the art will recognize that many modifications may be made to this configuration without departing from the scope of the present description, and that the article of manufacture may comprise suitable information bearing medium known in the art. Of course, those skilled in the art will recognize that many modifications may be made to this configuration without departing from the scope of the present description, and that the article of manufacture may comprise any tangible information bearing medium known in the art.

In certain applications, a device in accordance with the present description, may be embodied in a computer system including a video controller to render information to display on a monitor or other display coupled to the computer system, a device driver and a network controller, such as a computer system comprising a desktop, workstation, server, mainframe, laptop, handheld computer, etc. Alternatively, the device embodiments may be embodied in a computing device that does not include, for example, a video controller, such as a switch, router, etc., or does not include a network controller, for example.

The illustrated logic of figures may show certain events occurring in a certain order. In alternative embodiments, certain operations may be performed in a different order, modified or removed. Moreover, operations may be added to the above described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to limit to the precise form disclosed. Many modifications and variations are possible in light of the above teaching.

What is claimed is:

1. An apparatus, comprising:
a memory having a block of bitcells logically divided into a plurality of memory sections, each memory section having a plurality of bitcells which include at least one of operational bitcells and both operational bitcells and a defective bitcell of a first type, each operational bitcell configured to store charge representing either a first logical bit value or a second logical bit value different from the first logical bit value, and each defective bitcell of the first type having a fixed read output at the first logical value; and
a memory controller comprising data transfer logic configured to store data into and read data from the memory, said data transfer logic including memory circuit defect correction logic configured to logically divide a block of data bits including user data bits, into a plurality of data bit sections, each data bit section to be written into an associated memory section of the block of the memory and, for each data bit section and its associated memory section, to selectively flip the logical values of all the user data bits of the data bit section so that the logical value of a user data bit to be written into a defective bitcell of a first type, matches the fixed read output at the first logical value.

2. The apparatus of claim 1 wherein each memory section further has a plurality of bitcells which include at least one of said operational bitcells and both said operational bitcells and a defective bitcell of a second type, each defective bitcell of the second type having a fixed read output at the second logical value, and wherein the memory circuit defect correction logic is further configured to, for each data bit section and its associated memory section, selectively flip the logical values of all the user data bits of the data bit section so that the logical value of a user data bit to be written into a defective bitcell of the second type matches the fixed read output at the second logical value.

3. The apparatus of claim 1 wherein each memory section further has a flip-flag bitcell, the data transfer logic is further configured to store each data bit section into its associated memory section, and the memory circuit defect correction logic is further configured, for each memory section, to set a flip-flag in the flip-flag bitcell for the associated memory section to indicate whether the logical values of all the user data bits of the data bit section stored in the associated memory section were flipped.

4. The apparatus of claim 3 wherein the data transfer logic is further configured to read the data bit section stored in each memory section, and the memory circuit defect correction logic is further configured to selectively re-flip the logical values of all the user data bits of the data bit section read from a memory section if the flip-flag bitcell for the associated memory section indicates that the logical values of all the user data bits of the data bit section stored in the associated memory section were flipped.

5. The apparatus of claim 1 wherein the memory circuit defect correction logic is further configured to, for each memory section having at least one defective bitcell, identify the location of each such defective bitcell in the memory section.

6. The apparatus of claim 5 wherein the memory circuit defect correction logic is further configured to determine whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

7. The apparatus of claim 3 wherein the memory circuit defect correction logic is further configured so that the setting a flip-flag includes setting the logical value of the flip-flag bitcell for the associated memory section.

8. The apparatus of claim 1 wherein each block of data bits includes at least 100 bits of data, wherein the memory circuit defect correction logic is further configured so that the logically dividing the block of data bits includes logically dividing the block of data bits into at least ten of said data bit sections, wherein each data bit section has at least ten data bits and wherein the block of memory has at least a hundred of said memory sections.

9. The apparatus of claim 1 wherein the memory controller further has error correction code logic configured to encode the user data bits of each data bit section in an error correction code, and to decode the encoded read data using the error correction code.

10. A method, comprising:
logically dividing a block of data bits including user data bits, into a plurality of data bit sections, each data bit section to be written into an associated memory section of a block of memory logically divided into a plurality memory sections, each memory section having a plurality of operational bitcells, each operational bitcell for storing charge representing either a first logical bit value or a second logical bit value different from the first logical bit value; and
for each data bit section and its associated memory section, selectively flipping the logical values of all the user data bits of the data bit section so that the logical value of a user data bit to be written into a defective bitcell of a first type identified as having a fixed read output at the first logical value, matches the fixed read output at the first logical value.

11. The method of claim 10 further comprising, for each data bit section and its associated memory section, selectively flipping the logical values of all the user data bits of the data bit section so that the logical value of a user data bit to be written into a defective bitcell of a second type identified as having a fixed read output at the second logical value, matches the fixed read output at the second logical value.

12. The method of claim 10 further comprising:
storing each data bit section into its associated memory section; and
for each memory section, setting a flip-flag for the associated memory section to indicate whether the logical values of all the user data bits of the data bit section stored in the associated memory section were flipped.

13. The method of claim 12 further comprising:
reading the user data bit section stored in each memory section; and
selectively re-flipping the logical values of all the user data bits of the data bit section read from a memory section if the flip-flag for the associated memory section indicates that the logical values of all the user data bits of the data bit section stored in the associated memory section were flipped.

14. The method of claim 10 further comprising for each memory section having at least one defective bitcell, identifying the location of each such defective bitcell in the memory section.

15. The method of claim 14 wherein the selective flipping includes determining whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

16. The method of claim 12 wherein the setting a flip-flag includes setting the logical value of a bitcell for the associated memory section.

17. The method of claim 10 wherein each block of data bits includes at least 100 bits of data, wherein the logically dividing the block of data bits includes logically dividing the block of data bits into at least ten of said data bit sections, wherein each data bit section has at least ten data bits and wherein the block of memory has at least a hundred of said memory sections.

18. A system for use with a display, comprising:
a processor;
a video controller configured to control the display in response to the processor;
a memory having a block of bitcells logically divided into a plurality of memory sections, each memory section having a plurality of bitcells which include at least one of operational bitcells and both operational bitcells and a defective bitcell of a first type, each operational bitcell configured to store charge representing either a first logical bit value or a second logical bit value different from the first logical bit value, and each defective bitcell of the first type having a fixed read output at the first logical value; and
a memory controller comprising data transfer logic configured to store data into and read data from the memory, said data transfer logic including memory circuit defect correction logic configured to logically divide a block of data bits including user data bits, into a plurality of data bit sections, each data bit section to be written into an associated memory section of the block of the memory and, for each data bit section and its associated memory section, to selectively flip the logical values of all the user data bits of the data bit section so that the logical value of a user data bit to be written into a defective bitcell of a first type, matches the fixed read output at the first logical value.

19. The system of claim 18 wherein each memory section further has a plurality of bitcells which include at least one of said operational bitcells and both said operational bitcells and a defective bitcell of a second type, each defective bitcell of the second type having a fixed read output at the second logical value, and wherein the memory circuit defect correction logic is further configured to, for each data bit section and its associated memory section, selectively flip the logical values of all the user data bits of the data bit section so that the logical value of a user data bit to be written into a defective bitcell of the second type matches the fixed read output at the , second logical value.

20. The system of claim 18 wherein each memory section further has a flip-flag bitcell, the data transfer logic is further configured to store each data bit section into its associated memory section, and the memory circuit defect correction logic is further configured, for each memory section, to set a flip-flag in the flip-flag bitcell for the associated memory section to indicate whether the logical values of all the user data bits of the data bit section stored in the associated memory section were flipped.

21. The system of claim 20 wherein the data transfer logic is further configured to read the data bit section stored in each memory section, and the memory circuit defect correction logic is further configured to selectively re-flip the logical values of all the user data bits of the data bit section read from a memory section if the flip-flag bitcell for the associated memory section indicates that the logical values of all the user data bits of the data bit section stored in the associated memory section were flipped.

22. The system of claim 18 wherein the memory circuit defect correction logic is further configured to, for each memory section having at least one defective bitcell, identify the location of each such defective bitcell in the memory section.

23. The system of claim 22 wherein the memory circuit defect correction logic is further configured to determine whether the logical value of a user data bit to be written to an identified location of a defective bitcell of the first type, is the second logical value, and if so, flipping the logical values of all the user data bits of the data bit section so that the logical value of the user data bit to be written to an identified location of a defective bitcell of the first type, matches the first logical value.

24. The system of claim 18 wherein each block of data bits includes at least 100 bits of data, wherein the memory circuit defect correction logic is further configured so that the logically dividing the block of data bits includes logically dividing the block of data bits into at least ten of said data bit sections, wherein each data bit section has at least ten data bits and wherein the block of memory has at least a hundred of said memory sections.

25. The system of claim 18 wherein the memory controller further has error correction code logic configured to encode the user data bits of each data bit section in an error correction code, and to decode the encoded read data using the error correction code.
